(19) United States
(12) Patent Application Publication
(10) Pub. No.: US 2020/0118985 A1
(43) Pub. Date: Apr. 16, 2020

(54) SEMICONDUCTOR PACKAGE

(71) Applicant: SAMSUNG ELECTRONICS CO., LTD., Suwon-si (KR)

(72) Inventors: Seung Hun CHAE, Suwon-si (KR); Young Kwan Seo, Suwon-si (KR); So Yeon Moon, Suwon-si (KR); Jung Hyun Lee, Suwon-si (KR); Hye Yeong Jo, Suwon-si (KR)

(73) Assignee: SAMSUNG ELECTRONICS CO., LTD., Suwon-si (KR)

(21) Appl. No.: 16/544,247

(22) Filed: Aug. 19, 2019

(30) Foreign Application Priority Data
Oct. 16, 2018 (KR) 10-2018-0123049

(51) Int. Cl. H01L 25/16; H01L 23/538; H01L 23/31; H01L 23/00

(52) U.S. Cl. CPC H01L 25/16; H01L 23/5383; H01L 23/3135; H01L 2224/02379; H01L 2224/02331; H01L 2224/02377; H01L 24/05

(57) ABSTRACT

A semiconductor package includes a semiconductor, a passive component disposed in parallel with the semiconductor chip and having a connection electrode, and a connection structure on a lower surface of the passive component. The connection structure includes a first metal layer electrically connected to the connection electrode, a second metal layer on the same level as the first metal layer and disposed adjacent to the first metal layer, and a wiring insulating layer having an insulating region filling the first and second metal layers and extending in one direction. A minimum width of the insulating region is referred to as a first width, and a shortest distance between one end of the passive component and one end of the insulating region on the same level is referred to as a spacing distance, and the spacing distance may be twice or more than the first width.

### CROSS-REFERENCE TO RELATED APPLICATION(S)

This application claims benefit of priority to Korean Patent Application No. 10-2018-0123049 filed on Oct. 16, 2018 in the Korean Intellectual Property Office, the disclosure of which is incorporated herein by reference in its entirety.

### TECHNICAL FIELD

The present disclosure relates to a semiconductor package including a semiconductor chip and a passive component.

### BACKGROUND

In the field of semiconductor packaging technology, there has been continuous demand for small-sized semiconductor chips in terms of a form of a semiconductor chip, and in terms of functions of a semiconductor chip, a technique of a system in package (SiP) requiring complexation and multifunctionality has been demanded. To achieve this, there has been increased interest in a technique of mounting a plurality of chips and components in a single package.

Particularly, in the semiconductor package including an IC chip and passive components, there is demand for a structure for preventing defects such as cracks and interface peeling due to a difference in coefficients of thermal expansion (CTE) between an encapsulant for encapsulating the passive components and a connection structure for the lower redistribution.

### SUMMARY

An aspect of the present disclosure is to provide a semiconductor package capable of preventing occurrence of defects of the connection structure in a lower portion of the passive component.

According to an aspect of the present disclosure, in a semiconductor package, a position of an insulating region of the connection structure in a lower portion of the passive component is optimized.

For example, a semiconductor package includes: a semiconductor chip having an active surface on which a connection pad is disposed and an inactive surface opposing the active surface; a passive component disposed in parallel with the semiconductor chip and having a connection electrode; a connection structure disposed on the active surface of the semiconductor chip and a lower surface of the passive component, and including a redistribution layer electrically connected to the connection pad; and an encapsulant covering at least portions of each of the semiconductor chip and the passive component, wherein the connection structure further comprises a first metal layer electrically connected to the connection electrode, a second metal layer located on the same level as the first metal layer and disposed adjacent to the first metal layer, the second metal layer being spaced apart from the first metal layer, and a wiring insulating layer having an insulating region filling a space between the first and second metal layers and extending in one direction. The insulating region overlaps with the passive component in a stacking direction and at least a portion of the insulating region overlaps with the connection electrode. A minimum width of the insulating region between the first and second metal layers is referred to as a first width, a shortest distance between one end of the passive component and one end of the insulating region on the same level is referred to as a spacing distance, and the spacing distance is twice or more than the first width.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view illustrating an example of an electronic device;

FIGS. 3A and 3B are schematic cross-sectional views illustrating states of a fan-in semiconductor package before and after being packaged;

FIG. 4 is a schematic cross-sectional view illustrating a packaging process of a fan-in semiconductor package;

FIG. 5 is a schematic cross-sectional view illustrating a case in which a fan-in semiconductor package is mounted on an interposer substrate and is ultimately mounted on a mainboard of an electronic device;

FIG. 6 is a schematic cross-sectional view illustrating a case in which a fan-in semiconductor package is embedded in an interposer substrate and is ultimately mounted on a mainboard of an electronic device;

FIG. 7 is a schematic cross-sectional view illustrating a fan-out semiconductor package;

FIG. 8 is a schematic cross-sectional view illustrating a case in which a fan-out semiconductor package is mounted on a mainboard of an electronic device;

FIG. 9 is a schematic cross-sectional view illustrating an example of a semiconductor package;

FIG. 10 is a schematic cross-sectional view taken along line I-I′ of the semiconductor package of FIG. 9;

FIGS. 11A to 11E are schematic plan views illustrating another example of a semiconductor package;

FIG. 12 is a schematic cross-sectional view illustrating another example of a semiconductor package; and

FIG. 13 is a schematic plan view illustrating an effect in a case in which the semiconductor package according to the disclosure is applied to an electronic device.

### DETAILED DESCRIPTION

Hereinafter, embodiments of the present disclosure will be described as follows with reference to the attached drawings. In the drawings, sizes and shapes of elements will be exaggerated or reduced for clear description.

Electronic Device

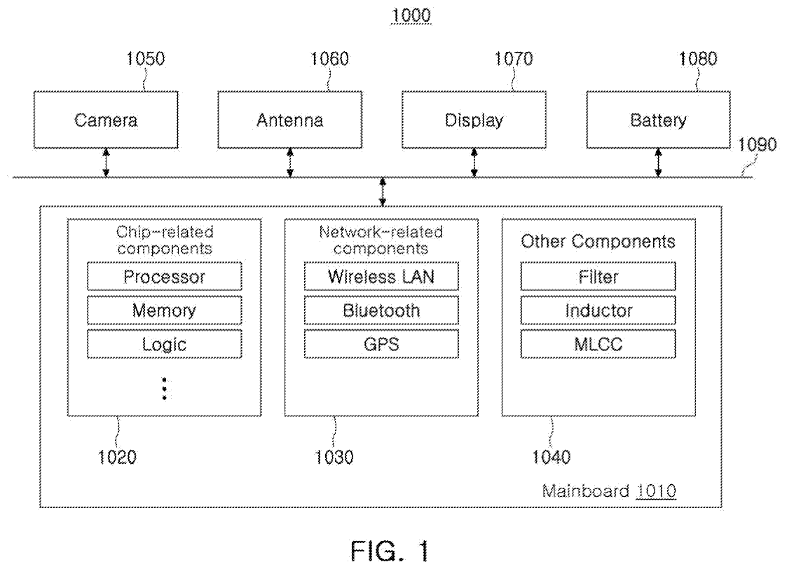

FIG. 1 is a schematic block diagram illustrating an example of an electronic device system.

Referring to FIG. 1, an electronic device 1000 may receive a motherboard 1010. The mother board 1010 may include chip related components 1020, network related components 1030, other components 1040, or the like, physically or electrically connected thereto. These components may be connected to others to be described below to form various signal lines 1090.

The chip associated components 1020 may include a memory chip such as a volatile memory (for example, a dynamic random access memory (DRAM)), a non-volatile memory (for example, a read only memory (ROM)), a flash memory, or the like; an application processor chip such as a central processor (for example, a central processing unit (CPU)), a graphics processor (for example, a graphics processing unit (GPU)), a digital signal processor, a cryptographic processor, a microprocessor, a microcontroller, or the like; and a logic chip such as an analog-to-digital converter, an application-specific integrated circuit (ASIC), or the like, or the like. However, the chip associated components 1020 are not limited thereto, and may include other types of chip associated components. In addition, the chip-associated components 1020 may be combined with each other.

The network associated components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3 G, 4G, and 5G protocols, and any other wireless and wired protocols, designated after the abovementioned protocols. However, the network associated components 1030 are not limited thereto, but may also include a variety of other wireless or wired standards or protocols. In addition, the network associated components 1030 may be combined with each other, together with the chip associated components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, but may also include passive components used for various other purposes, or the like. In addition, other components 1040 may be combined with each other, together with the chip related components 1020 or the network related components 1030 described above.

Depending on a type of the electronic device 1000, the electronic device 1000 includes other components that may or may not be physically or electrically connected to the mainboard 1010. These other components may include, for example, a camera 1050, an antenna 1060, a display 1070, a battery 1080, an audio codec (not illustrated), a video codec (not illustrated), a power amplifier (not illustrated), a compass (not illustrated), an accelerometer (not illustrated), a gyroscope (not illustrated), a speaker (not illustrated), a mass storage unit (for example, a hard disk drive) (not illustrated), a compact disk (CD) drive (not illustrated), a digital versatile disk (DVD) drive (not illustrated), or the like. However, these other components are not limited thereto, but may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device able to process data.

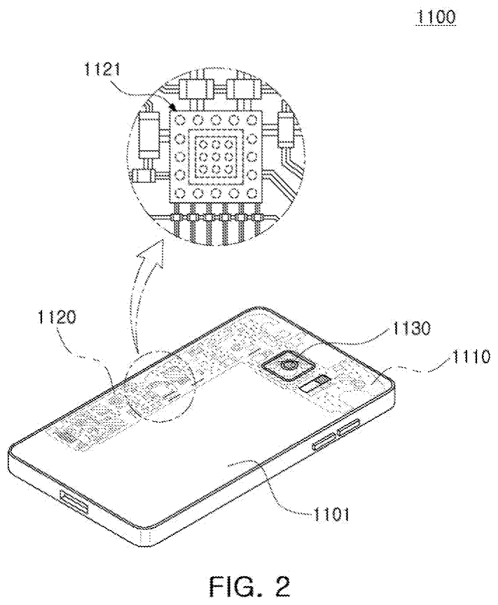

FIG. 2 is a schematic perspective view illustrating an example of an electronic device.

Referring to FIG. 2, a semiconductor package may be used for various purposes in the various electronic devices 1000 as described above. For example, a printed circuit board 1110 may be accommodated in a body 1101 of a smartphone 1100, and various electronic components 1120 may be physically or electrically connected to the printed circuit board 1110. In addition, other components that may or may not be physically or electrically connected to the printed circuit board 1110, such as a camera module 1130, may be accommodated in the body 1101. Some of the electronic components 1120 may be the chip related components, for example, a semiconductor package 1121, but are not limited thereto. The electronic device is not necessarily limited to the smartphone 1100, but may be other electronic devices as described above.

Semiconductor Package

Generally, numerous fine electrical circuits are integrated in a semiconductor chip. However, the semiconductor chip may not serve as a finished semiconductor product in itself, and may be damaged due to external physical or chemical impacts. Therefore, the semiconductor chip itself may not be used, but may be packaged and used in an electronic device, or the like, in a packaged state.

Here, semiconductor packaging is required due to the existence of a difference in a circuit width between the semiconductor chip and a mainboard of the electronic device in terms of electrical connections. In detail, a size of connection pads of the semiconductor chip and an interval between the connection pads of the semiconductor chip are very fine, but a size of component mounting pads of the mainboard used in the electronic device and an interval between the component mounting pads of the mainboard are significantly larger than those of the semiconductor chip. Therefore, it may be difficult to directly mount the semiconductor chip on the mainboard, and packaging technology for buffering a difference in a circuit width between the semiconductor chip and the mainboard is required.

A semiconductor package manufactured by the packaging technology may be classified as a fan-in semiconductor package or a fan-out semiconductor package depending on a structure and a purpose thereof.

The fan-in semiconductor package and the fan-out semiconductor package will hereinafter be described in more detail with reference to the drawings.

Fan-In Semiconductor Package

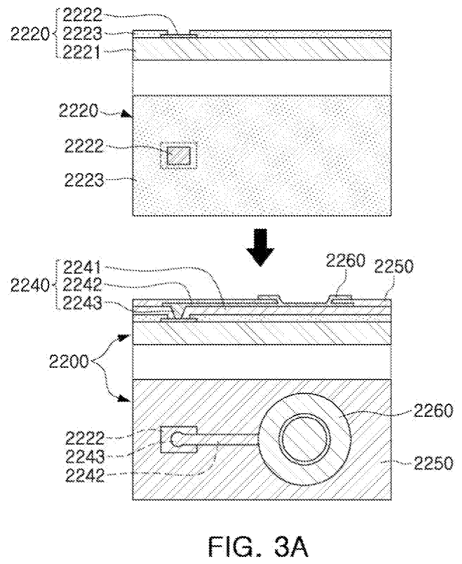

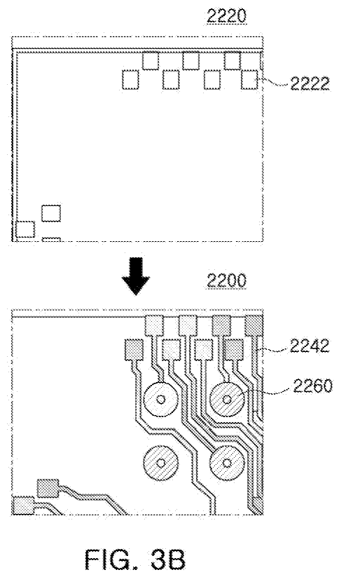

FIGS. 3A and 3B are schematic cross-sectional views illustrating states of a fan-in semiconductor package before and after being packaged.

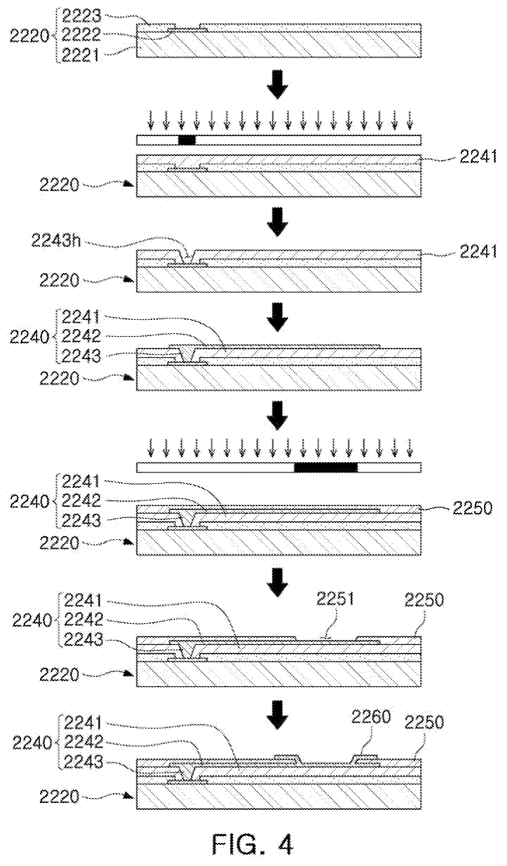

FIG. 4 is a schematic cross-sectional view illustrating a packaging process of a fan-in semiconductor package.

Referring to FIGS. 3A to 4, a semiconductor chip 2220 may be, for example, an integrated circuit (IC) in a bare state, including a body 2221 including silicon (Si), germanium (Ge), gallium arsenide (GaAs), or the like, connection pads 2222 formed on one surface of the body 2221 and including a conductive material such as aluminum (Al), or the like, and a passivation layer 2223 such as an oxide layer, a nitride layer, or the like, formed on one surface of the body 2221 and covering at least portions of the connection pads 2222. In this case, since the connection pads 2222 may be significantly small, it may be difficult to mount the integrated circuit (IC) on an intermediate level printed circuit board (PCB) as well as on the mainboard of the electronic device, or the like.

Therefore, a connection structure 2240 may be formed depending on a size of the semiconductor chip 2220 on the semiconductor chip 2220 in order to redistribute the connection pads 2222. The connection structure 2240 may be formed by forming an insulating layer 2241 on the semiconductor chip 2220 using an insulating material such as a photoimagable dielectric (PID) resin, forming via holes 2243h opening the connection pads 2222, and then forming wiring patterns 2242 and vias 2243. Then, a passivation layer 2250 protecting the connection structure 2240 may be formed, an opening 2251 may be formed, and an underbump metal layer 2260, or the like, may be formed. That is, a fan-in semiconductor package 2200 including, for example, the semiconductor chip 2220, the connection structure 2240, the passivation layer 2250, and the underbump metal layer 2260 may be manufactured through a series of processes.

As described above, the fan-in semiconductor package may have a package form in which all of the connection pads, for example, input/output (I/O) terminals, of the semiconductor chip are disposed inside the semiconductor chip, and may have excellent electrical characteristics and be produced at low cost. Therefore, many elements mounted in smartphones have been manufactured in a fan-in semiconductor package form. In detail, many elements mounted in smartphones have been developed to implement a rapid signal transfer while having a compact size.

However, since all I/O terminals need to be disposed inside the semiconductor chip in the fan-in semiconductor package, the fan-in semiconductor package has significant spatial limitations. Therefore, it is difficult to apply this structure to a semiconductor chip having a large number of I/O terminals or a semiconductor chip having a compact size. In addition, due to the disadvantage described above, the fan-in semiconductor package may not be directly mounted and used on the mainboard of the electronic device. Here, even in a case in which a size of the I/O terminals of the semiconductor chip and an interval between the I/O terminals of the semiconductor chip are increased by a redistribution process, the size of the I/O terminals of the semiconductor chip and the interval between the I/O terminals of the semiconductor chip may not be sufficient to directly mount the fan-in semiconductor package on the mainboard of the electronic device.

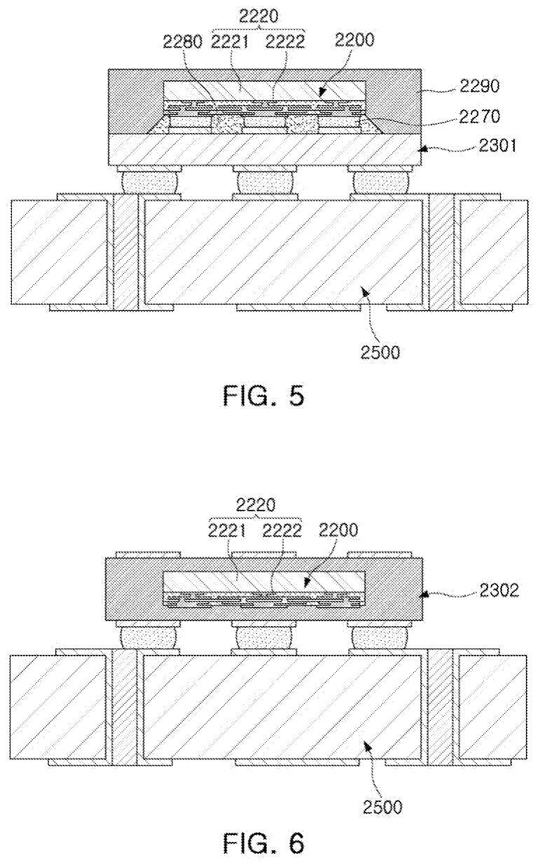

FIG. 5 is a schematic cross-sectional view illustrating a case in which a fan-in semiconductor package is mounted on an interposer substrate and is ultimately mounted on a mainboard of an electronic device.

FIG. 6 is a schematic cross-sectional view illustrating a case in which a fan-in semiconductor package is embedded in an interposer substrate and is ultimately mounted on a mainboard of an electronic device.

Referring to FIGS. 5 and 6, in a fan-in semiconductor package 2200, connection pads 2222, that is, I/O terminals, of a semiconductor chip 2220 may be redistributed through an interposer substrate 2301, and the fan-in semiconductor package 2200 may ultimately be mounted on a mainboard 2500 of an electronic device in a state in which it is mounted on the interposer substrate 2301. In this case, solder balls 2270, and the like, may be fixed by an underfill resin 2280, or the like, and an outer side of the semiconductor chip 2220 may be covered with a molding material 2290, or the like. Alternatively, a fan-in semiconductor package 2200 may be embedded in a separate interposer substrate 2302, connection pads 2222, that is, I/O terminals, of the semiconductor chip 2220 may be redistributed by the interposer substrate 2302 in a state in which the fan-in semiconductor package 2200 is embedded in the interposer substrate 2302, and the fan-in semiconductor package 2200 may be ultimately mounted on a mainboard 2500 of an electronic device.

As described above, it may be difficult to directly mount and use the fan-in semiconductor package on the mainboard of the electronic device. Therefore, the fan-in semiconductor package may be mounted on the separate interposer substrate and be then mounted on the mainboard of the electronic device through a packaging process or may be mounted and used on the mainboard of the electronic device in a state in which it is embedded in the interposer substrate.

Fan-Out Semiconductor Package

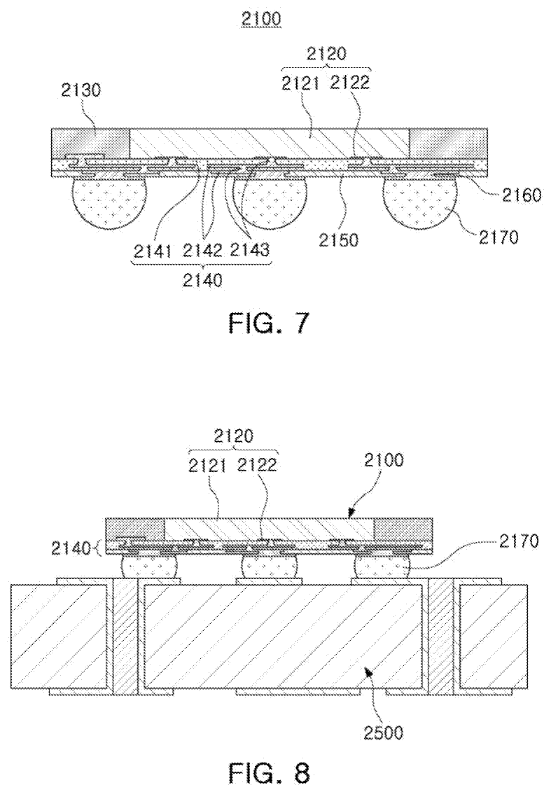

FIG. 7 is a schematic cross-sectional view illustrating a fan-out semiconductor package.

Referring to FIG. 7, in a fan-out semiconductor package 2100, for example, an outer side of a semiconductor chip 2120 may be protected by an encapsulant 2130, and connection pads 2122 of the semiconductor chip 2120 may be redistributed outwardly of the semiconductor chip 2120 by a connection structure 2140. In this case, a passivation layer 2202 may further be formed on the connection structure 2140, and an underbump metal layer 2160 may further be formed in openings of the passivation layer 2202. Solder balls 2170 may further be formed on the underbump metal layer 2160. The semiconductor chip 2120 may be an integrated circuit (IC) including a body 2121, the connection pads 2122, a passivation layer (not illustrated), and the like. The connection structure 2140 may include an insulating layer 2141, redistribution layers 2142 formed on the insulating layer 2141, and vias 2143 electrically connecting the connection pads 2122 and the redistribution layers 2142 to each other.

As described above, the fan-out semiconductor package may have a form in which I/O terminals of the semiconductor chip are redistributed and disposed outwardly of the semiconductor chip through the connection structure formed on the semiconductor chip. As described above, in the fan-in semiconductor package, all I/O terminals of the semiconductor chip need to be disposed inside the semiconductor chip. Therefore, when a size of the semiconductor chip is decreased, a size and a pitch of balls need to be decreased, such that a standardized ball layout may not be used in the fan-in semiconductor package. On the other hand, the fan-out semiconductor package has the form in which the I/O terminals of the semiconductor chip are redistributed and disposed outwardly of the semiconductor chip through the connection structure formed on the semiconductor chip as described above. Therefore, even in a case that a size of the semiconductor chip is decreased, a standardized ball layout may be used in the fan-out semiconductor package as it is, such that the fan-out semiconductor package may be mounted on the mainboard of the electronic device without using a separate printed circuit board, as described below.

FIG. 8 is a schematic cross-sectional view illustrating a case in which a fan-out semiconductor package is mounted on a mainboard of an electronic device.

Referring to FIG. 8, a fan-out semiconductor package 2100 may be mounted on a mainboard 2500 of an electronic device through solder balls 2170, or the like. That is, as described above, the fan-out semiconductor package 2100 includes the connection structure 2140 formed on the semiconductor chip 2120 and capable of redistributing the connection pads 2122 to a fan-out region that is outside of a size of the semiconductor chip 2120, such that the standardized ball layout may be used in the fan-out semiconductor package 2100 as it is. As a result, the fan-out semiconductor package 2100 may be mounted on the mainboard 2500 of the electronic device without using a separate interposer substrate, or the like.

As described above, since the fan-out semiconductor package may be mounted on the mainboard of the electronic device without using the separate interposer substrate, the fan-out semiconductor package may be implemented at a thickness lower than that of the fan-in semiconductor package using the interposer substrate. Therefore, the fan-out semiconductor package may be miniaturized and thinned. In addition, the fan-out semiconductor package has excellent thermal characteristics and electrical characteristics, such that it is particularly appropriate for a mobile product. Therefore, the fan-out electronic component package may be implemented in a form more compact than that of a general package-on-package (POP) type using a printed circuit board (PCB), and may solve a problem due to the occurrence of a warpage phenomenon.

Meanwhile, the fan-out semiconductor package refers to package technology for mounting the semiconductor chip on the mainboard of the electronic device, or the like, as described above, and protecting the semiconductor chip from external impacts, and is a concept different from that of a printed circuit board (PCB) such as an interposer substrate, or the like, having a scale, a purpose, and the like, different from those of the fan-out semiconductor package, and having the fan-in semiconductor package embedded therein.

Hereinafter, a semiconductor package, capable of preventing defects in the connection structure in a lower portion of the passive component will be described with reference to the drawings.

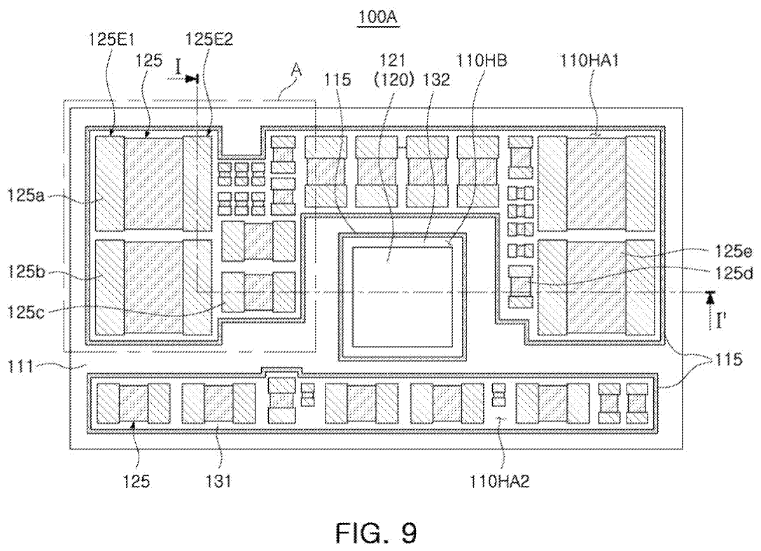

FIG. 9 is a schematic plan view illustrating an example of a semiconductor package.

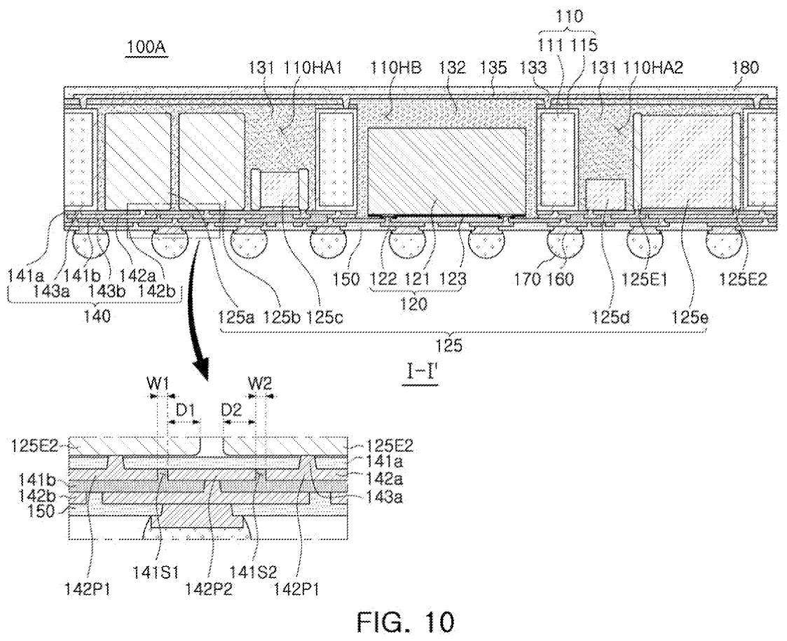

FIG. 10 is a schematic cross-sectional view taken along line I-I′ of the semiconductor package of FIG. 9.

Referring to FIGS. 9 and 10, a semiconductor package 100A according to an embodiment may include a frame 110 having first through-holes 110HA1 and 110HA2 and a second through-hole 110HB, at least one passive component 125 and at least one passive component 125 respectively disposed in the first through-holes 110HA1 and 110HA2 of the frame 110, a semiconductor chip 120 disposed in the second through-hole 110HB of the frame 110, and having an active surface on which the connection pad 122 is disposed, and an inactive surface opposing the active surface, a first encapsulant 131 encapsulating at least portions of the frame 110 and the passive component 125, a second encapsulant 132 encapsulating at least portions of the frame 110 and the semiconductor chip 120, a connection structure 140 disposed on the frame 110, a lower surface of the passive component 125, and the active surface of the semiconductor chip 120, and including first redistribution layers 142a and 142b electrically connected to the connection pad 122, a first passivation layer 150 disposed on the connection structure 140, an underbump metal layer 160 disposed on an opening of the first passivation layer 150, an electrical connection metal 170 disposed on the first passivation layer 150 and connected to the underbump metal layer 160, a backside redistribution layer 135 and a backside via 133 disposed on the upper surface of the frame 110, and a second passivation layer 180 disposed on the upper surface of the second encapsulant 132 so as to cover the backside redistribution layer 135. The connection structure 140 may include a first insulating layer 141a disposed on the passive component 125, a first redistribution layer 142a disposed on the first insulating layer 141a, a first via 143a connecting the first redistribution layer 142a, the passive component 125, and the metal layer 115, a second insulating layer 141b disposed on the first insulating layer 141a, a second redistribution layer 142b disposed on the second insulating layer 141b, and a second via 143b connecting the first and second redistribution layers 142a and 142b or connecting the connection pad 122 of the semiconductor chip 120 and the second redistribution layer 142b while penetrating the second insulating layer 141b. The first redistribution layer 142a may be electrically connected to the passive component 125, and the second redistribution layer 142b may be electrically connected to the connection pad 122 of the semiconductor chip 120 and the passive component 125.

In particular, the connection structure 140 may further include a first metal layer 142P1 disposed on a plane so as to be overlapped with a portion of the passive component 125 and electrically connected to connection electrodes 125E1 and 125E2, a second metal layer 142P2 disposed adjacent to the first metal layer 142P1, and the second insulating layer 141b having insulating regions 141S1 and 141S2 extending in one direction between the first and second metal layers 142P1 and 142P2. The first redistribution layer 142a may include the first and second metal layers 142P1 and 142P2, and the second insulating layer 141b may include the insulating layers 141S1 and 141S2. The second metal layer 142P2 may be disposed between the first metal layers 142P1. The first metal layers 142P1 may be connected to the connection structures 125E1 and 125E2, respectively, which are not connected to the second metal layer 142P2. Or the second metal layer 142P2 may receive a separate electrical signal without being connected to the connection electrodes 125E1 and 125E2. In this case, for example, a ground voltage may be applied to the second metal layer 142P2.

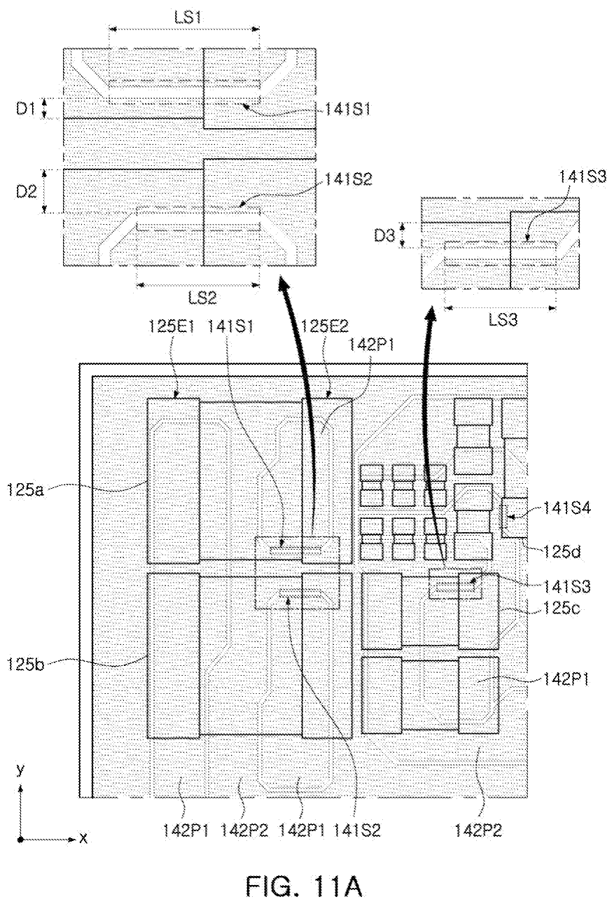

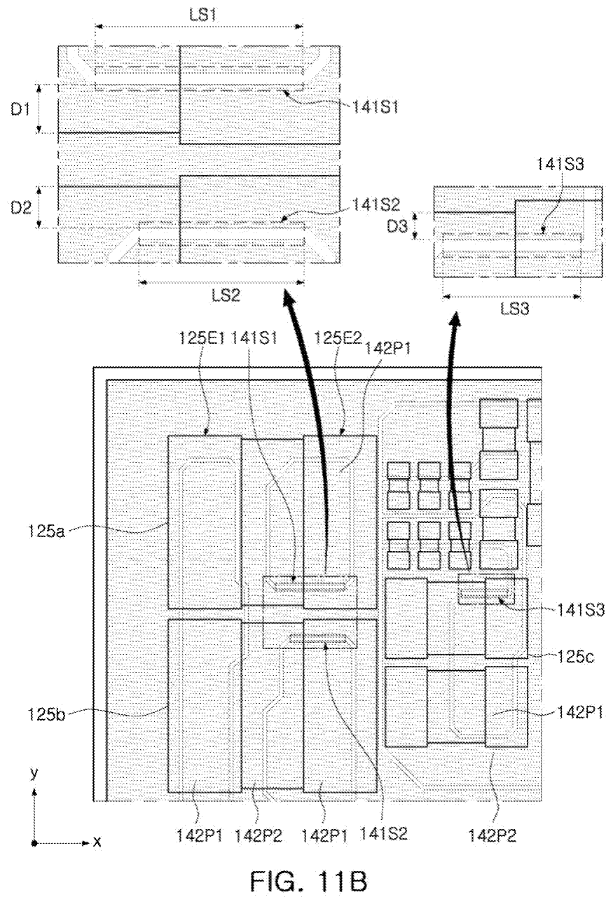

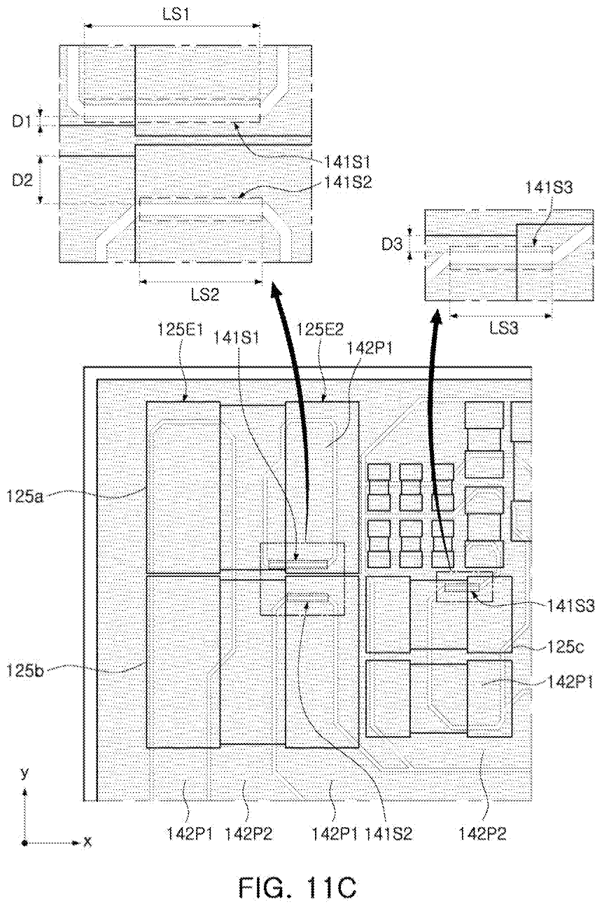

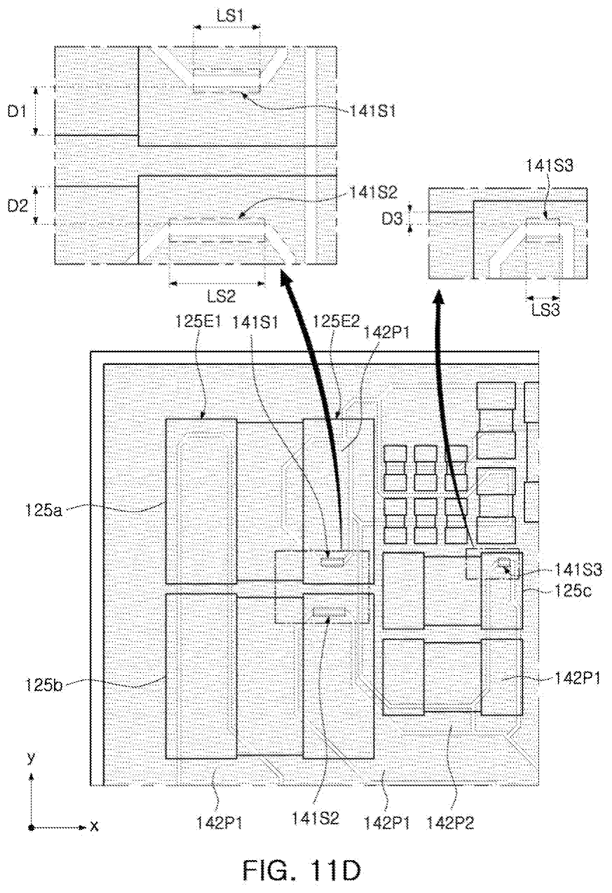

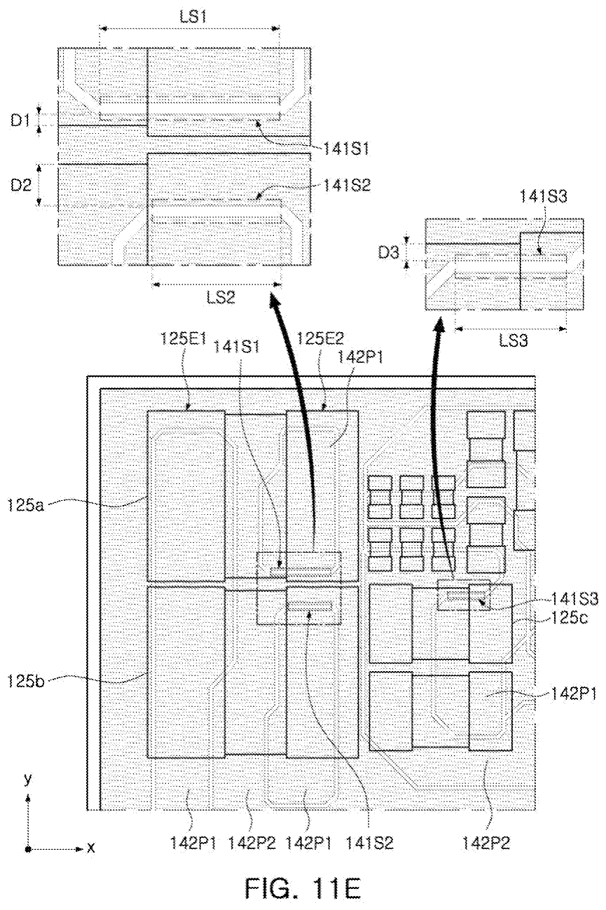

The insulating regions 141S1 and 141S2 may be regions extending in parallel with the end portion in a region adjacent to end portions of the first and second passive components 125a and 125b. The insulating regions 141S1 and 141S2 may be disposed such that an entirety of the insulating regions 141S1 and 141S2 overlap with the first and second passive components 125a and 125b on the plane, and at least portions thereof overlap with the connection electrodes 125E1 and 125E2. This will be described in more detail below with reference to FIGS. 11A to 11E. The first insulating region 141S1 may have a first width W1, a minimum width, and may be spaced apart from the end portion of the first passive component 125a by a first spacing distance D1, a shortest distance in a horizontal direction, to be located in a lower portion of the first passive component 125a. The second insulating region 141S2 may have a second width W2, a minimum width, and may be spaced apart from the end portion of the second passive component 125b by a second spacing distance D2 in a horizontal direction to be located in a lower portion of the second passive component 125b. The first spacing distance D1 and the second spacing distance D2 may be at least twice or more than each of the first width W1 and the second width W2. Alternately, at least one of the first spacing distance D1 and the second spacing distance D2 may be at least twice or more than each of the first width W1 and the second width W2.

The first insulating layer 141a in an uppermost portion of the connection structure 140 and the second insulating layer 141b in a lower portion thereof may be made of different materials. For example, the first insulating layer 141a may be formed of a non-photosensitive material, and the second insulating layer 141b may be formed of a photosensitive material. For example, the first insulating layer 141a may be an Ajinomoto Build-up Film (ABF), and the second insulating layer 141b may be a PID resin. The first encapsulant 131 may encapsulate at least a portion of the lower surface of the passive component 125, and for example, may include the same or similar material as the first insulating layer 141a. In this case, when a difference in coefficient expansion (CTE) may occur between the passive components 125, the first insulating layer 141a, the second insulating layer 141b, and the metal layers 141P1 and 141P2, having different materials, and when the end portion of the passive component 125, that is, side surfaces thereof are disposed in parallel to a direction perpendicular to the end portions of the metal layers 142P1 and 142P2, stress may be concentrated on the end portions, such that defects such as cracks and peeling may occur in the connection structure 140. However, in the semiconductor package 100A according to an example, since the insulating regions 141S1 and 141S2 between the metal layers 142P1 and 142P2 are disposed in a lower portion of the passive component 125 by a predetermined distance, such that the occurrence of such defects may be significantly reduced. In particular, since the spacing distance is specifically limited in relation to the width of the insulating regions 141S1 and 141S2, the disposition of the metal layers 142P1 and 142P2 may be efficiently optimized while significantly reducing the occurrence of defects and the resistance between the metal layers 142P1 and 142P2 and the connection electrodes 125E1 and 125E2 may be secured.

Hereinafter, each configuration included in the semiconductor package 100A according to an example will be described in more detail.

The frame 110 may improve rigidity of the semiconductor package 100A depending on certain materials, and serve to secure uniformity of thicknesses of the first and second encapsulants 131 and 132. The frame 110 has a plurality of first and second through-holes 110HA1 and 110HA2, and 110HB. The first and second through-holes 110HA1 and 110HA2, and 110HB may be disposed to be physically spaced apart from each other. The first through-holes 110HA1 and 110HA2 may penetrate the frame 110, while the passive component 125 may be disposed in the first through-holes 110HA1 and 110HA2. As illustrated in FIG. 9, the passive component 125 may be disposed to be spaced apart from wall surfaces of the first through-holes 110HA1 and 110HA2 by a predetermined distance, and may be surrounded by the wall surfaces of the first through-holes 110HA1 and 110HA2, but are not limited thereto. The second through-hole 110HB may penetrate the frame 110 and the first encapsulant 131, while the semiconductor chip 120 may be disposed in the second through-hole 110HB. The semiconductor chip 120 may be disposed to be spaced apart from a wall surface of the second through-hole 110HB by a predetermined distance, and may be surrounded by the wall surface of the second through-hole 110HB. However, such a form is only an example and may be variously modified to have other forms, and another function may be performed depending on such a form. The frame 110 may be omitted if necessary, but the case having the frame 110 may be more advantageous in securing board level reliability as intended in the present disclosure.

The frame 110 may include a frame insulating layer 111 and a metal layer 115 surrounding the frame insulating layer 111. An insulating material may be used as the material of the frame insulating layer 111. In this case, the insulating material may be a thermosetting resin such as an epoxy resin, a thermoplastic resin such as a polyimide resin, an insulating material in which the thermosetting resin or the thermoplastic resin is impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Such a frame 110 may serve as a supporting member.

The metal layer 115 may be disposed in an inner side wall of each of the first through-holes 110HA1 and 110HA2 and the second through-hole 110HB. As illustrated in FIG. 9, the metal layer 115 may surround each of the passive component 125 and the semiconductor chip 120. The metal layer 115 may be introduced to improve an electromagnetic interference (EMI) shielding effect and a heat dissipation effect of the passive component 125 and the semiconductor chip 120. The metal layer 115 may include a conductive material such as copper (Cu), aluminum (Al), silver (Ag), tin (Sn), gold (Au), nickel (Ni), lead (Pb), titanium (Ti), or alloys thereof. The metal layer 115 may be formed using a known plating process, and may be formed of a seed layer and a conductor layer. The metal layer 115 may be used as a ground. In this case, the metal layer 115 may be electrically connected to a ground pattern layer in the connection structure 140.

The semiconductor chip 120 may be an integrated circuit (IC) provided in an amount of several hundred to several million or more elements integrated in a single chip. The IC may be, for example, a processor chip such as a central processor (for example, a central processing unit (CPU)), a graphics processor (for example, a graphics processing unit (GPU)), a field programmable gate array (FPGA), a digital signal processor, a cryptographic processor, a microprocessor, a microcontroller, or the like, in detail, an application processor (AP). However, the present disclosure is not limited thereto, and the semiconductor chip may be a logic chip such as an analog-to-digital converter (ADC), an application-specific integrated circuit (ASIC), or the like, or a memory chip such as a volatile memory (for example, a dynamic random access memory (DRAM)), a non-volatile memory (for example, a read only memory (ROM)), a flash memory, or the like, but is not limited thereto Moreover, these chip related components are also combined.

In the semiconductor chip 120, a side, on which connection pad 122 is disposed, is an active surface, and the opposite side is an inactive surface. The semiconductor chip 120 may be formed on the basis of an active wafer. In this case, a base material of a body 121 of the semiconductor chip 120 may be silicon (Si), germanium (Ge), gallium arsenide (GaAs), or the like. Various circuits may be formed on the body 121. The connection pads 122 may electrically connect the semiconductor chip 120 to other components. A material of each of the connection pads 122 may be a conductive material such as aluminum (Al), or the like. A passivation film 123 exposing the connection pads 122 may be formed on the body 121, and may be an oxide film, a nitride film, or the like, or a double layer of an oxide film and a nitride film.

Each of the passive components 125 may be a capacitor such as a multilayer ceramic capacitor (MLCC) or a low inductance chip capacitor (LICC), an inductor such as a power inductor, a bead, or the like, independently. For example, among the passive components 125 as illustrated in FIG. 10, the first, second, and fifth passive components 125a, 125b, and 125e may correspond to power inductors, and third and fourth passive components 125c and 125d may correspond to MLCC. The passive component 125 may have different sizes and thicknesses. Moreover, the passive component 125 may have a thickness from a thickness of the semiconductor chip 120. In the semiconductor package 100A according to an example, the passive component 125 and the semiconductor chip 120 are encapsulated in different processes, so a problem of defects due to such thickness variations may be significantly reduced. The number of the passive component 125 is not particularly limited, and may be more or less than that illustrated in the drawings.

The first encapsulant 131 may fill at least portions of the first through-holes 110HA1 and 110HA2, and may encapsulate one or more passive components 125. An encapsulation form of the first encapsulant 131 is not particularly limited, but may be a form in which the first encapsulant 131 surrounds at least portions of the passive component 125. The first encapsulant 131 may cover at least portions of an upper surface and a lower surface of the passive component 125, and may fill at least a portion of a space between wall surfaces of the first through-holes 110HA1 and 110HA2 and side surfaces of a plurality of passive components 125. The first encapsulant 131 may extend to the frame 110 to be disposed on the frame 110, and may be in contact with an upper surface of the metal layer 115.

The second encapsulant 132 may fill at least a portion of the second through-hole 110HB, while encapsulating the semiconductor chip 120. An encapsulation form of the second encapsulant 132 is not particularly limited, but may be a form in which the second encapsulant 132 surrounds at least a portion of the semiconductor chip 120. In this case, the second encapsulant 132 may cover at least portions of the frame 110 and an inactive surface of the semiconductor chip 120, and fill at least a portion of a space between a wall surface of the second through-hole 110HB and a side surface of the semiconductor chip 120. Meanwhile, the second encapsulant 132 may fill the second through-hole 110HB to thus serve as an adhesive for fixing the semiconductor chip 120 and reduce buckling at the same time, depending on certain materials. The second encapsulant 132 is disposed in an upper portion of the semiconductor chip 120 as described above, may extend to upper portions of the passive component 125 and the frame 110, and may be disposed on the first encapsulant 131, on the passive components 125 and the frame 110. Thus, the first and second encapsulants 131 and 132 are stacked sequentially and disposed on the passive component 125 and the frame 110. The second encapsulant 132 may be only one of the first encapsulant 131 and the second encapsulant 132 that is disposed on the semiconductor chip 120.

The first and second encapsulants 131 and 132 may include an insulating material. The insulating material may be a material containing an inorganic filler and an insulating resin, for example, a thermosetting resin such as an epoxy resin, a thermoplastic resin such as a polyimide, or a resin in which a reinforcement such as an inorganic filler is contained in the thermosetting resin or the thermoplastic resin, in detail, an Ajinomoto build-up film (ABF), an FR-4 resin, a bismaleimide triazine (BT) resin, a resin, or the like. Moreover, an epoxy molding compound (EMC), a photo imageable encapsulant (PIE), or the like, may be used therefor. As needed, a material in which an insulating resin such as the thermosetting resin or the thermoplastic resin is impregnated in an inorganic filler together with a core material such as a glass fiber, may be used. The first and second encapsulants 131 and 132 may include the same or different materials.

The connection structure 140 may redistribute the connection pads 122 of the semiconductor chip 120. Several tens to several hundreds of connection pads 122 of the semiconductor chip 120 having various functions may be redistributed by the connection structure 140, and may be physically and/or electrically externally connected through the electrical connection metal 170 depending on functions. The connection structure 140 may include the number of insulating layers, redistribution layers, and vias, greater than illustrated in the drawings.

The second redistribution layer 142b, among the redistribution layers 142a and 142b, may substantially serve to redistribute the connection pads 122, and a formation material thereof may be a conductive material such as copper (Cu), aluminum (Al), silver (Ag), tin (Sn), gold (Au), nickel (Ni), lead (Pb), titanium (Ti), or alloys thereof. The redistribution layers 142a and 142b may perform various functions depending on designs of corresponding layers. For example, the redistribution layers 142a and 142b may include ground (GND) pattern layers 142G, and may further include power (PWR) patterns, signal (S) patterns, and the like. Here, the signal (S) patterns may include various signals except for the ground (GND) signals, the power (PWR) signals, and the like, such as data signals, and the like. Moreover, the redistribution layers 142a and 142b may include via pad patterns, electrical connection metal pad patterns, and the like.

The vias 143a and 143b may electrically connect the redistribution layers 142a and 142b, the connection pads 122, the passive component 125, and the like, formed on different layers, to each other, resulting in an electrical path in the semiconductor package 100A. A material of each of the vias 143a, and 143b may be a conductive material such as copper (Cu), aluminum (Al), silver (Ag), tin (Sn), gold (Au), nickel (Ni), lead (Pb), titanium (Ti), or alloys thereof. Each of the vias 143a and 143b may be completely filled with a conductive material, or the conductive material may be formed along a wall of a via hole. In addition, the vias 143a and 143b may have all shapes known in the related art, such as a tapered shape, a cylindrical shape, and the like.

A backside redistribution layer 135 may be disposed on the second encapsulant 132 to cover the semiconductor chip 120 and the passive component 125. The backside redistribution layer 135 may be connected to the metal layer 115 of the frame 110 through a backside via 133 penetrating the first and second encapsulants 131 and 132. The semiconductor chip 120 and the passive component 125 are surrounded by a metal material through the backside via 133, such that an EMI shielding effect and a heat dissipation effect may be further improved. The backside redistribution layer 135 and the backside via 133 may also include a conductive material such as copper (Cu), aluminum (Al), silver (Ag), tin (Sn), gold (Au), nickel (Ni), lead (Pb), titanium (Ti), or alloys thereof. The backside redistribution layer 135 and the backside via 133 may also be used as a ground and in this case, may be electrically connected to the ground of the redistribution layers 142a and 142b of the connection structure 140 via the metal layer 115. The backside redistribution layer 135 may be in a form of a plate covering most of the upper surface of the second encapsulant 132. The backside via 133 may be in a form of a trench via having a predetermined length. In this case, moving paths of electromagnetic waves become substantially clogged, and the electromagnetic wave shielding effect may be more excellent. However, the present disclosure is not limited thereto, and the backside redistribution layer 135 may have a form including a plurality of plates, in a range in which an effect of shielding electromagnetic waves is provided, and openings may be formed in the middle of the backside via 133 to provide a gas movement path.

The first passivation layer 150 may protect the connection structure 140 from external physical or chemical damage. The first passivation layer 150 may have an opening exposing at least a portion of the second redistribution layer 142b of the connection structure 140. The number of openings, formed in the first passivation layer 150, may be several tens to several thousands. A material of the first passivation layer 150 is not particularly limited. For example, an insulating material may be used. In this case, the insulating material may be a thermosetting resin such as an epoxy resin, a thermoplastic resin such as a polyimide resin, a resin in which the thermosetting resin or the thermoplastic resin is mixed with an inorganic filler or is impregnated together with an inorganic filler in a core material such as a glass fiber (or a glass cloth or a glass fabric), for example, prepreg, Ajinomoto Build-up Film (ABF), FR-4, Bismaleimide Triazine (BT), or the like. Alternatively, a solder resist may also be used therefor. A second passivation layer 180 may also be formed on the backside redistribution layer 135 to protect the backside redistribution layer 135. The first passivation layer 150 and the second passivation layer 180 may include the same material, thereby serving to control a coefficient of thermal expansion (CTE) due to an effect of symmetry.

The underbump metal layer 160 may improve connection reliability of the electrical connection metal 170 to improve board level reliability of the semiconductor package 100A. The underbump metal layer 160 may be connected to the second redistribution layer 142b of the connection structure 140, exposed through the openings of the first passivation layer 150. The underbump metal layer 160 may be formed in the openings of the first passivation layer 150 by any known metallization method using any known conductive material such as a metal, but is not limited thereto.

The electrical connection metal 170 physically and/or electrically connects the semiconductor package 100A to an external power source. For example, the semiconductor package 100A may be mounted on the mainboard of the electronic device through the electrical connection metal 170. The electrical connection metal 170 may be formed of a conductive material, for example, a solder or the like. However, this is only an example, and a material of each of the electrical connection metal 170 is not particularly limited thereto. Each of the electrical connection metals 170 may be a land, a ball, a pin, or the like. The electrical connection metals 170 may be formed as a multilayer or single layer structure. When the electrical connection metal 170 includes the plurality of layers, the electrical connection metal may include a copper pillar and a solder. When the electrical connection metal 170 includes the single layer, the electrical connection metal 170 may include a tin-silver solder or copper. However, the electrical connection metal is only an example, and the present disclosure is not limited thereto. The number, an interval, a disposition form, and the like, of the electrical connection metals 170 are not particularly limited, but may be sufficiently modified depending on design particulars by those skilled in the art. For example, the electrical connection metals 170 may be provided in an amount of several tens to several thousands, or may be provided in an amount of several tens to several thousands or more or several tens to several thousands or less.

At least one of the electrical connection metals 170 may be disposed in a fan-out region of the semiconductor chip 120. The fan-out region refers to a region except for a region in which the semiconductor chip 120 is disposed. The fan-out package may have excellent reliability as compared to a fan-in package, may allow a plurality of input/output (I/O) terminals to be implemented, and may facilitate a 3D interconnection. In addition, as compared to a ball grid array (BGA) package, a land grid array (LGA) package, or the like, the fan-out package may be manufactured to have a small thickness, and may have price competitiveness.

FIGS. 11A to 11E are schematic plan views illustrating another example of the semiconductor package. In FIGS. 11A to 11E, an area corresponding to the area ‘A’ in FIG. 9 are enlarged and illustrated.

Referring to FIGS. 11A to 11E, in the semiconductor package, the disposition of the first to third passive components 125a, 125b, and 125c and the metal layers 142P1 and 142P2 of the connection structure 140 in the lower portion thereof, and the insulating regions 141S1, 141S2, and 141S3 is specifically illustrated. As described above with reference to FIGS. 9 and 10, the insulating regions 141S1, 141S2, and 141S3 may be regions extending in parallel with the end portions in regions adjacent to the end portions of the first to third passive components 125a, 125b, and 125c. That is, the insulating regions 141S1, 141S2, and 141S3 may be portions of the second insulating layer 141b disposed between the metal layers 142P1 and 142P2, and may mean a region extending in one direction in an area adjacent to the end portion along one end portion of the first to third passive components 125a, 125b, and 125c, among the regions between the metal layers 142P1 and 142P2. At least portions of the insulating regions 141S1, 141S2, and 141S3 may be disposed to be overlapped with the connection electrodes 125E1 and 125E2 on the plane to be disposed in the lower portions of the first to third passive components 125a, 125b, and 125c.

In the lower portion of the first passive component 125a, the first insulating region 141S1 may have a first length LS1, and may be spaced apart by a first spacing distance D1 along a y direction perpendicular to a x direction, from an end portion of the first passive component 125a extending in the x direction while facing the second passive component 125b. In the lower portion of the second passive component 125b, the second insulating region 141S2 may have a second length LS2, and may be spaced apart by a second spacing distance D2 from an end portion of the second passive component 125b opposing the first passive component 125a. In the lower portion of the third passive component 125c, the third insulating region 141S3 may have a third length LS3, and may be spaced apart by a third spacing distance D3 from an end portion of the third passive component 125c. The first to third spacing distances D1, D2, and D3 may be twice or more of the width in the y direction of the insulating regions 141S1, 141S2, and 141S3, respectively.

However, it is not necessarily that all of the insulating regions in the lower portion of all the passive components 125 are disposed to be spaced apart by a predetermined distance from the adjacent end portion of the passive component 125, such as the first to third insulating regions 141S1, 141S2, and 141S3. The insulating regions may be disposed in the form of the present disclosure in at least the portions of the passive components 125, and at least a portion of the insulating region may be disposed even in the lower portion of the passive component 125 as described above. As shown in Table 1 below, various kinds of passive components 125 may be mounted in one package, and the passive components 125 may have different sizes. In Table 1, a length may mean a dimension of the passive component 125 in the x direction of the drawing, and a width may mean a dimension of the passive component 125 in the y direction. As shown in Table 1, when the passive component 125 has a size, greater than a specific size, cracks tend to occur. Thus, when the passive component has a predetermined width or more, for example, a minimum width of 1 mm or more, a width along a minor axis, the insulating region may be spaced apart by a spacing distance from the adjacent end portion of the passive component 125 as described above. For example, in FIGS. 11A to 11E, the first and second passive components 125a and 125b may be winding or power inductors, and the third passive component 125c may be a first MLCC.

TABLE 1

| Kinds | Sizes of passive | | Occurrence |
|---|---|---|---|
| of passive | components [mm] | | rate of |
| components | x direction | y direction | cracks [%] |
| Winding power | 2.58 | 2.14 | 3.33 |
| inductor | | | |
| Thin-film power | 2.64 | 2.14 | 6.25 |
| inductor | | | |
| First MLCC | 1.80 | 1.00 | 12.50 |
| Second MLCC | 1.00 | 0.50 | 0 |
| Third MLCC | 0.60 | 0.30 | 0 |

In addition, according to embodiments, when warpage of the package mainly occurs in a specific direction, and accordingly, the progress of cracks is affected, the insulating region adjacent to the end portion along a direction in which the crack mainly proceeds may be disposed to be spaced apart by a predetermined distance from the adjacent end portion of the passive component 125 such as the first to the third insulating regions 141S1, 141S2, and 141S3. That is, among the insulating regions adjacent to the first to third passive components 125a, 125b, and 125c, in particular, an insulating region including the first to third insulating regions 141S1, 141S2, and 141S3 extending in the x direction may be disposed in the form of the present disclosure. For example, in FIG. 11A, in a fourth passive component 125d, in a fourth insulating region 141S4, a spacing distance from an end portion of the passive component 125d may be smaller than the first to third spacing distances D1, D2, and D3, and may be overlapped with the end portion of the fourth passive component 125d.

In the first to fifth embodiments of FIGS. 11A to 11E, the lengths LS1, LS2, and LS3 of the first to third spacing distances D1, D2, and D3 and the first to third insulating regions 141S1, 141S2, and 141S3 may be the same or different from each other, and may have the values shown in Table 2 below. In the embodiments, each of the first to third spacing distances D1, D2, and D3 may be greater than in a comparative example, or at least two thereof may be greater than in the comparative example. An average value of the first to third spacing distances D1, D2, and D3 may be greater than that of the comparative example. In addition, in the embodiments, each of the lengths LS1, LS2, and LS3 of the first to third insulating regions 141S1, 141S2, and 141S3 may be smaller than in the comparative example, or at least two may be smaller than that of the comparative example. In addition, the average value of the lengths LS1, LS2, and LS3 may be smaller than that of the comparative example. In the third and fifth embodiments, the numerical values are the same, but the shapes in the regions in which the metal layers 142P1 and 142P2 extend are different from each other. In the embodiments, widths of the insulating regions 141S1, 141S2, and 141S3 may be in a range from about 25 μm to 35 μm. Therefore, in the embodiments, at least two of the first to third spacing distances D1, D2, and D3 may be greater than twice the width of the insulating region.

TABLE 2

| | D1 | D2 | D3 | LS1 | LS2 | LS3 |
|---|---|---|---|---|---|---|
| | [μm] | [μm] | [μm] | [μm] | [μm] | [μm] |
| Comparative | 20 | 40 | 10 | 915 | 700 | 470 |
| example | | | | | | |
| First | 40 | 220 | 130 | 740 | 540 | 470 |
| embodiment | | | | | | |
| Second | 260 | 240 | 180 | 900 | 660 | 580 |
| embodiment | | | | | | |
| Third | 40 | 220 | 130 | 740 | 540 | 470 |
| embodiment | | | | | | |
| Fourth | 260 | 240 | 10 | 300 | 400 | 170 |
| embodiment | | | | | | |
| Fifth | 40 | 220 | 130 | 740 | 540 | 470 |
| embodiment | | | | | | |

The first to third spacing distances D1, D2, and D3 may range from about 1.5% to 15.0% of the width in the y direction of the first to third passive components 125a, 125b, and 125c. When the spacing distance is greater than the above-mentioned range, the electrical resistance between the connection electrodes 125E1 and 125E2 and the metal layers 142P1 and 142P2 may increase, and when the spacing distance is smaller than the above-mentioned range, a failure of the connection structure 140 may occur. In addition, the lengths LS1, LS2, and LS3 may range from about 10.0% to 35.0% of the width in the x direction of the first to third passive components 125a, 125b, and 125c. When the length is smaller than the above-mentioned range, the contact area between the connection electrodes 125E1 and 125E2 and the metal layers 142P1 and 142P2 may decrease and the resistance may increase. When the length is greater than the above-mentioned range, the length extending in parallel with the end portion may increase, such that the failure rate of the connection structure 140 may increase.

In the embodiments, the first to third insulating regions 141S1, 141S2, and 141S3 along one direction, for example, the x direction, may have a length ranging from about 10.0% to 25.0% of the width in the x direction of the first to third passive components 125a, 125b, and 125c, particularly ranging from about 10.0% to 29.0%, and may have a spacing distance ranging from about 1.5% to 15.0% of the width in the y direction, particularly ranging from about 7.0% to 13.0%, in a region adjacent to the first to third passive components 125a, 125b, and 125c. In addition, when the first and second passive components 125a and 125b corresponding to a case in which the passive component 125 having the largest size in the package is disposed to face each other, at least one of the insulating regions 141S1 and 141S2 along the end portions opposing each other may be disposed in a lower portion by a distance of two or more of the width of the insulating region, and may have a length less than 26.0% of the width in the x direction of the first and second passive components 125a and 125b.

Referring to Table 3, in the first to fifth embodiments, the occurrence rate of cracks was 0 to 0.21%, as compared with the occurrence rate of cracks in the comparative example was 22.36% on average. Therefore, it can be seen that the occurrence of cracks in the connection structure 140 may be reduced by the disposition of the metal layers 142P1 and 142P2 and thus the positions of the insulating regions 141S1, 141S2, and 141S3.

TABLE 3

| | Occurrence rate |
|---|---|
| | of cracks [%] |
| Comparative | 22.36 |
| example | |
| First | 0 |
| embodiment | |
| Second | 0 |
| embodiment | |
| Third | 0.21 |
| embodiment | |
| Fourth | 0 |
| embodiment | |
| Fifth | 0 |
| embodiment | |

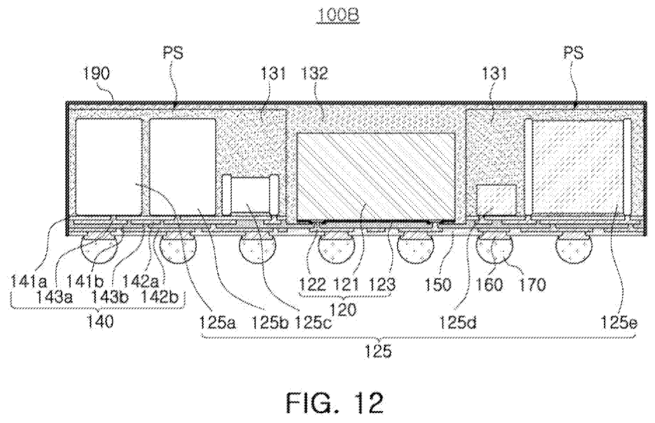

FIG. 12 is a schematic cross-sectional view illustrating another example of a semiconductor package.

Referring to FIG. 12, in a semiconductor package 100B according to another example, the passive component 125 disposed in parallel with the semiconductor chip 120 may form one or more component built-in structures PS. The component built-in structure PS may include the passive component 125, the first encapsulant 131, and the first insulating layer 141a, the first redistribution layer 142a, and the first via 143 of the connection structure 140. The component built-in structure PS may be a form in which the frame 110 of FIG. 10 is omitted, but it is possible to further include the frame 110 according to the embodiments. In addition, the semiconductor package 100B may further include an upper metal layer 190 disposed on an outside of the package so as to form portions of an upper surface and a side surface. EMI shielding of the package may be further enhanced by the upper metal layer 190. The upper metal layer 190 may cover the upper surface of the second encapsulant 132, and side surfaces of the component built-in structure PS and the connection structure 140, and may cover at least a portion of the first passivation layer 150. The upper metal layer 190 may include a metal material such as copper (Cu), aluminum (Al), silver (Ag), tin (Sn), gold (Au), nickel (Ni), lead (Pb), titanium (Ti), or alloys thereof. Other configurations are substantially the same as those described in the above-described semiconductor package 100A and the like, and a detailed description thereof will be omitted.

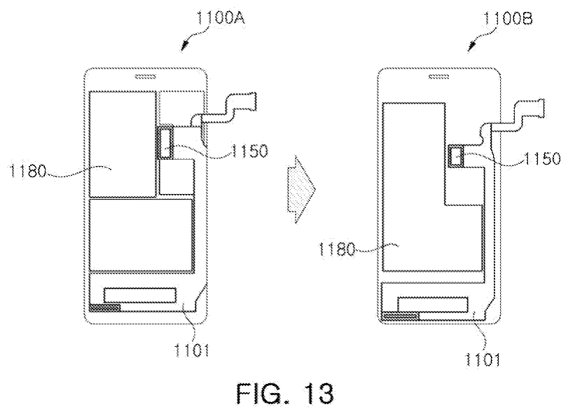

FIG. 13 is a schematic plan view illustrating an effect in a case in which the semiconductor package according to the present disclosure is applied to an electronic device.

Referring to FIG. 13, recently, as a size of displays for mobile devices 1100A and 1100B have increase, the necessity of increasing battery capacity is increasing. As the battery capacity increases, an area occupied by the battery 1180 increases. In this regard, a size of a printed circuit board 1101 such as a mainboard is required to be reduced. Thus, due to a reduction in a mounting area of a component, an area occupied by a module 1150 including a power management integrated circuit (PMIC) and passive components is gradually decreased. In this case, when the semiconductor packages 100A, 100B, 100C, and 100D according to an embodiment is applied to the module 1150, a size is able to be reduced. Thus, the area, which becomes smaller as described, above may be effectively used.

As set forth above, according to an embodiment in the present disclosure, a semiconductor package capable of preventing occurrence of defects of a connection structure in a lower portion of the passive component may be provided.

The present disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

Throughout the specification, it will be understood that when an element, such as a layer, region or wafer (substrate), is referred to as being “on,” “connected to,” or “coupled to” another element, it can be directly “on,” “connected to,” or “coupled to” the other element or other elements intervening therebetween may be present. In contrast, when an element is referred to as being “directly on,” “directly connected to,” or “directly coupled to” another element, there may be no elements or layers intervening therebetween. Like numerals refer to like elements throughout. As used herein, the term “and/or” includes any and all combinations of one or more of the associated listed items.

It will be apparent that though the terms first, second, third, etc. may be used herein to describe various members, components, regions, layers and/or sections, these members, components, regions, layers and/or sections should not be limited by these terms. These terms are only used to distinguish one member, component, region, layer or section from another region, layer or section. Thus, a first member, component, region, layer or section discussed below could be termed a second member, component, region, layer or section without departing from the teachings of the exemplary embodiments.

Spatially relative terms, such as “above,” “upper,” “below,” and “lower” and the like, may be used herein for ease of description to describe one element's relationship to another element(s) as shown in the figures. It will be understood that the spatially relative terms are intended to encompass different orientations of the device in use or operation in addition to the orientation depicted in the figures. For example, if the device in the figures is turned over, elements described as “above,” or “upper” other elements would then be oriented “below,” or “lower” the other elements or features. Thus, the term “above” can encompass both the above and below orientations depending on a particular direction of the figures. The device may be otherwise oriented (rotated 90 degrees or at other orientations) and the spatially relative descriptors used herein may be interpreted accordingly.

The terminology used herein describes particular embodiments only, and the present disclosure is not limited thereby. As used herein, the singular forms “a,” “an,” and “the” are intended to include the plural forms as well, unless the context clearly indicates otherwise. It will be further understood that the terms “comprises,” and/or “comprising” when used in this specification, specify the presence of stated features, integers, steps, operations, members, elements, and/or groups thereof, but do not preclude the presence or addition of one or more other features, integers, steps, operations, members, elements, and/or groups thereof.

Hereinafter, embodiments of the present disclosure will be described with reference to schematic views illustrating embodiments of the present disclosure. In the drawings, for example, due to manufacturing techniques and/or tolerances, modifications of the shape shown may be estimated. Thus, embodiments of the present disclosure should not be construed as being limited to the particular shapes of regions shown herein, for example, to include a change in shape results in manufacturing. The following embodiments may also be constituted by one or a combination thereof.

The contents of the present disclosure described below may have a variety of configurations and propose only a required configuration herein, but are not limited thereto.

While the exemplary embodiments have been shown and described above, it will be apparent to those skilled in the art that modifications and variations could be made without departing from the scope of the present invention as defined by the appended claims.

What is claimed is:

1. A semiconductor package, comprising:
a semiconductor chip having an active surface on which a connection pad is disposed and an inactive surface opposing the active surface;
a passive component disposed in parallel with the semiconductor chip and having a connection electrode;
a connection structure disposed on the active surface of the semiconductor chip and a lower surface of the passive component, and including a redistribution layer electrically connected to the connection pad; and
an encapsulant covering at least portions of each of the semiconductor chip and the passive component,
wherein the connection structure further comprises a first metal layer electrically connected to the connection electrode, a second metal layer located on the same level as the first metal layer and disposed adjacent to the first metal layer, the second metal layer being spaced apart from the first metal layer, and a wiring insulating layer having an insulating region filling a space between the first and second metal layers and extending in one direction,
wherein the insulating region overlaps with the passive component in a stacking direction, and at least a portion thereof overlaps with the connection electrode, and
wherein a minimum width of the insulating region is referred to as a first width between the first and second metal layers, and a shortest distance between one end of the passive component and one end of the insulating region on the same level is referred to as a spacing distance, and the spacing distance is twice or more than the first width.

2. The semiconductor package of claim 1, wherein the passive component has a minimum width, and the spacing distance is in a range of 1.5% to 15.0% of the minimum width.

3. The semiconductor package of claim 1, wherein the wiring insulating layer includes a first insulating layer in contact with the lower surface of the passive component, and a second insulating layer in which the first and second metal layers are disposed and which has the insulating region.

4. The semiconductor package of claim 3, wherein the first insulating layer and the second insulating layer include different materials.

5. The semiconductor package of claim 4, wherein the first insulating layer is a non-photosensitive material, and the second insulating layer is a photosensitive material.

6. The semiconductor package of claim 1, wherein the passive component includes inductors and capacitors having different sizes, and
the insulating region is disposed by the spacing distance in a lower portion of a portion of the passive component.

7. The semiconductor package of claim 6, wherein the insulating region is disposed in the lower portion of the passive component with a minimum width of 1 mm or more.

8. The semiconductor package of claim 1, wherein the passive component includes a power inductor.

9. The semiconductor package of claim 1, wherein the passive component has a third width along an extension direction of the insulating region, and
a length of the insulating region is in a range of 10.0% to 35.0% of the third width.

10. The semiconductor package of claim 1, wherein the encapsulant includes a first encapsulant encapsulating the passive component and a second encapsulant encapsulating the semiconductor chip.

11. The semiconductor package of claim 10, wherein the lower surface of the passive component has a step with the active surface of the semiconductor chip.

12. The semiconductor package of claim 1, further comprising a frame disposed on the connection structure, and having a first through-hole in which the passive component is disposed and a second through-hole in which the semiconductor chip is disposed.

13. The semiconductor package of claim 12, wherein the encapsulant covers at least a portion of an upper surface of the frame.

14. The semiconductor package of claim 1, wherein in a cross-section perpendicular to the one direction, an entirety of the insulating region overlaps with the passive component in the stacking direction.

15. A semiconductor package, comprising:
first and second passive components having a connection electrode and disposed in parallel with each other;
a connection structure including a first metal layer disposed in a lower portion of the first passive component and electrically connected to the connection electrode, a second metal layer disposed adjacent to the first metal layer, and a wiring insulating layer having a first insulating layer filling a space between the first and second metal layers; and
an encapsulant covering at least portions of the first and second passive components,
wherein the first insulating region overlaps with the first passive component in a stacking direction, and at least a portion thereof overlaps with the connection electrode,
wherein a minimum width of the insulating region is referred to as a first width, and a shortest distance on the same level between one end of the first passive component facing the second passive component and one end of the insulating region is referred to as a first spacing distance, and the first spacing distance is at least twice or more than the first width.

16. The semiconductor package of claim 15, further comprising a third passive component having a smaller size than the first and second passive components,
wherein the connection structure further comprises third and fourth metal layers spaced apart from each other in a lower portion of the third passive component, and the wiring insulating layer further comprises a second insulating region filling a space between the third and fourth metal layers,
the second insulating region is located in the lower portion of the third passive component, and
the second insulating region is spaced apart from one end of the third passive component by a second spacing distance smaller than the first spacing distance.

17. The semiconductor package of claim 15, wherein the insulating region extends in a first direction, and
one end of the first passive component spaced apart from the insulating region by the first spacing distance extends in the first direction.

18. The semiconductor package of claim 17, wherein in a cross-section perpendicular to the first direction, an entirety of the first insulating region overlaps with the first passive component in the stacking direction.
